(19) United States
(12) Patent Application Publication
(10) Pub. No.: US 2004/0079936 A1
(43) Pub. Date: Apr. 29, 2004

(54) Semiconductor memory device

(75) Inventors: Hidemoto Tomita, Tokyo (JP); Nobuyuki Kokubo, Tokyo (JP); Akira Hosogane, Tokyo (JP)

Correspondence Address: McDERMOTT, WILL & EMERY, 600 13th Street, N.W., Washington, DC, 20005-3096, US

(73) Assignee: RENESAS TECHNOLOGY CORP.

(21) Appl. No.: 10/670,396

(22) Filed: Sep. 26, 2003

(30) Foreign Application Priority Data
Oct. 29, 2002 (JP) 2002-314307

(51) Int. Cl. H01L 47/00

(52) U.S. Cl. 257/1

(57) ABSTRACT

A semiconductor memory device operating in synchronization with an external clock signal, includes memory cells arrayed in two dimension, word lines and bit lines connected to the memory cells, IO lines connected to the bit lines, and a sense amplifier connected to the IO lines and activated by a sense amplifier enable signal. After the word line is selected, an internal clock signal is generated by delaying the rising and falling edges of the external clock signal input to the memory device. A timing at which the internal clock signal changes from a first state to a second state is delayed by a predetermined time to make the sense amplifier enable signal active, and a timing at which the internal clock signal changes from the second state to the first state is delayed by a shorter period than the predetermined time to make the sense amplifier enable signal inactive.

### BACKGROUND OF THE INVENTION

1. Field of the Invention

The present invention relates to a semiconductor, memory device capable of performing a data read/write operation in synchronous with an external clock signal, and more particularly to a circuit operable to generate a signal for activating a sense amplifier which amplifies a voltage appearing on bit lines.

2. Related Art

There has been known a synchronous SRAM capable of performing a data read/write operation in synchronous with a clock signal received from an external devices (hereinafter referred to as “external clock”) as one type of semiconductor memories. In the synchronous SRAM, when an external clock signal is entered into the synchronous SRAM and then a target memory cell is selected, a voltage corresponding to a data value of the selected memory cell is generated on bit lines. The voltage appearing on the bit lines is an undetectable level of small voltage, and thus it is amplified by a sense amplifier and then output to a data bus.

After a memory cell is selected, a voltage corresponding to data will appear on the bit lines gradually as a time elapses. If the sense amplifier is activated just after the selection of the memory cell, the sense amplifier will amplify an insufficient level of voltage on the bit lines likely to generate an incorrect data. Thus, it is required to activate the sense amplifier after a certain time has passed from the selection of the memory cell to allow the bit-line voltage to be changed to a sufficient level.

For this purpose, a sense amplifier enable signal for activating the sense amplifier is generated by delaying an internal clock signal which is generated from the external clock signal by a predetermined time.

Regarding the synchronous SRAM, during a “High” state of the internal clock signal, a memory cell is selected and data read or write operation is done. During a “Low” state of the internal clock signal, memory cells, bit lines and data lines are initialized to prepare for the next cycle.

In the above synchronous SRAM, if the timing of initiating the activation of the sense amplifier is delayed (that is, delay amount of the internal clock signal for generating a sense amplifier enable signal is increased) to obtain the aforementioned sufficient level of bit-line voltage, the timing of inactivating the sense amplifier will be delayed accordingly, which leads to a reduced time-period of the initialization for the next cycle. This results in insufficient initialization and causes operational defects.

Aftertime, an initialization period of memory cells, bit lines, data lines and other will be more reduced as a frequency of the clock signal is increased in connection with the advance of high-speed semiconductor memory device, and therefore the above problem will be more critical.

### SUMMARY OF THE INVENTION

In view of the above problem, it is therefore an object of the present invention to provide a semiconductor memory device including a signal generating circuit for generating an enable signal of a sense amplifier, capable of assuring an adequate initialization period and preventing an incorrect read operation even in use of a high-speed clock signal.

In order to achieve this object, the present invention provides a semiconductor memory device operating in synchronization with an external clock signal, including memory cells arrayed in two dimension, word lines and bit lines connected to the memory cells, IO lines connected to the bit lines, and a sense amplifier connected to the IO lines and activated by a sense amplifier enable signal. After the word line is selected, an internal clock signal is generated by delaying the rising and falling edges of the external clock signal input to the memory device. A timing at which the internal clock signal changes from a first state to a second state is delayed by a predetermined time to make the sense amplifier enable signal active, and a timing at which the internal clock signal changes from the second state to the first state is delayed by a shorter period than the predetermined time to make the sense amplifier enable signal inactive.

The present invention also provides a semiconductor memory device operating in synchronization with an external clock signal, including memory cells arrayed in two dimension, word lines and bit lines connected to memory cells, IO lines connected to bit lines, a sense amplifier connected to the IO lines and activated by a sense amplifier enable signal, a first delay circuit operable to delay an internal clock signal by a first predetermined time, the internal clock signal being generated by delaying the rising and falling edges of the external clock signal input to the memory device after the word line is selected, a second delay circuit operable to delay the internal clock signal by a second predetermined time, and an AND circuit operable to logically multiply an output signal from the first delay circuit and an output signal from the second delay circuit to generate the sense amplifier enable signal.

According to the present invention, it is possible to provide a semiconductor memory device including a signal generating circuit operable to generate a signal for activating a sense amplifier with a simplified structure while assuring a sufficient initialization period and preventing an incorrect reading, even if using a high speed clock signal.

Other features and advantages of the present invention will be apparent from the accompanying drawings and from the detailed description.

### BRIEF DESCRIPTION OF THE DRAWINGS

FIG. 1 is a block diagram of a signal generating circuit generating an SE signal generating circuit according to a first embodiment of the present invention.

FIG. 2 is a block diagram of a semiconductor memory using the SE signal generating circuit.

FIG. 3 is a view showing a structure of a memory cell array in FIG. 2.

FIG. 4 is a detailed block diagram of a block 10 in FIG. 2.

FIG. 5A is a view showing a waveform of an internal clock signal X to be entered into the SE signal generating circuit.

FIG. 5B is a view showing a waveform of an output signal from a delay circuit.

FIG. 5C is a view showing a waveform of an output signal from the SE signal generating circuit.

FIGS. 6A to 6J are views showing explanatory waveforms of signals at respective sections of the semiconductor memory during data read operation.

FIG. 7 is a block diagram of a SE signal generating circuit according to a second embodiment of the present invention.

FIGS. 8A to 8D are views showing waveforms of signals at respective sections of the SE signal generating circuit according to the second embodiment (in case of outputting a SE signal having a falling timing advanced by a time t0 with respect to that of the input internal clock signal).

FIGS. 9A to 9D are views showing waveforms of signals at respective sections of the SE signal generating circuit according to the second embodiment (in case of outputting a SE signal having a rising timing delayed by a time t0 with respect to that of the input internal clock signal).

### DESCRIPTION OF THE PREFERRED EMBODIMENTS

With reference to accompanying drawings, a semiconductor memory device according to preferred embodiments of the present invention will now be described in detail.

### First Embodiment

A semiconductor memory as described below is a semiconductor memory device which reads or writes data in synchronous with an external clock signal, which can be suitably applied to, for example, a synchronous SRAM.

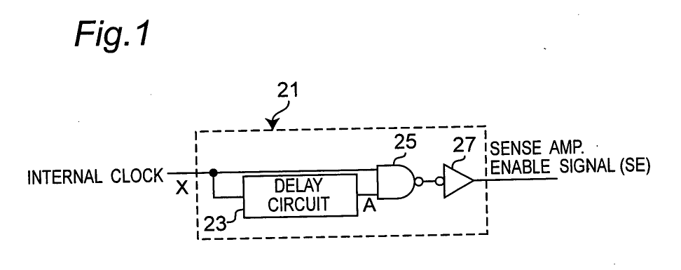

FIG. 1 is a block diagram of a signal generating circuit (hereinafter referred to as “SE signal generating circuit”) which is used in the semiconductor memory, according to the first embodiment of the present invention. The SE signal generating circuit 21 generates a sense amplifier enable signal (hereinafter referred to as “SE signal”) for activating a sense amplifier to amplify minute level of voltage appearing on a bit line pair during an operation of reading data stored in the semiconductor memory. The SE signal generating circuit 21 includes a delay circuit 23 for delaying by a predetermined time an internal clock signal which is produced by delaying an external clock signal, and a combination of a NAND gate 25 and an inverter 27 which perform an AND operation (conjunction) of the internal clock signal and the delayed clock signal from the delay circuit 23. The SE signal generating circuit 21 outputs a result of the AND operation as a SE signal.

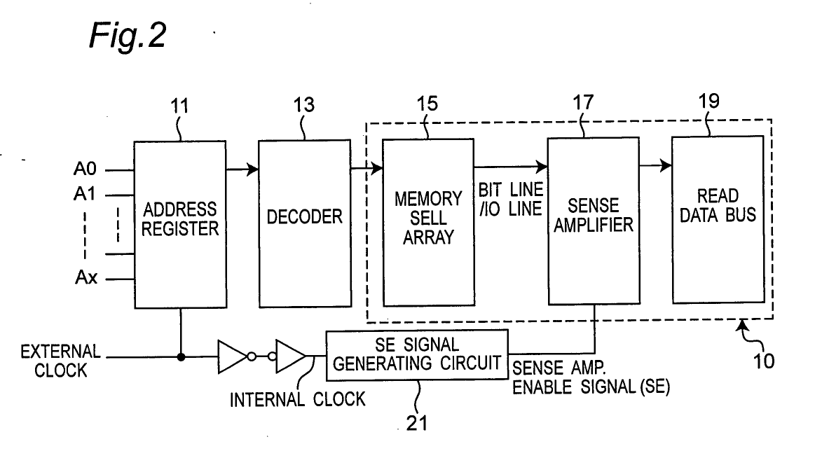

FIG. 2 is a block diagram of a semiconductor memory using the SE signal generating circuit 21. The semiconductor memory includes an address register 11 which stores an entered read/write address, a decoder 13 which decodes the entered address, a memory cell array 15 which includes a plurality of memory cells each having data stored thereon, a sense amplifier 17 which amplifies the minute voltage on the bit-line pair connected to the corresponding memory cell, and a read data bus 19 on which read data appears.

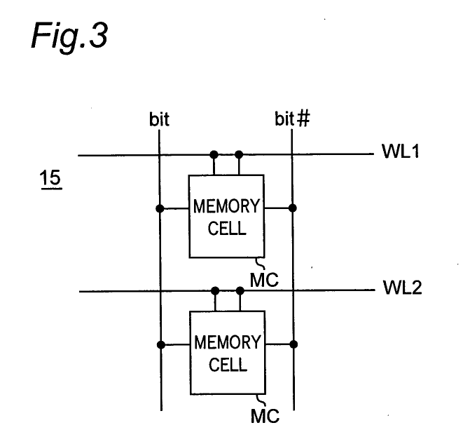

FIG. 3 shows a structure of the memory cell array 15. The memory cell array 15 includes a plurality of memory cells MC each storing data therein. Each of the memory cells MC is connected with a bit line pair “bit” and “bit#”, and a word line WL1 or WL2. It should be noted that the symbol “#” added to the tail of the signal line name or signal name means the inversion of a data value or an active-low. For example, the bit line “bit#” has a logical data value corresponding to an inverse data value of the bit line “bit”.

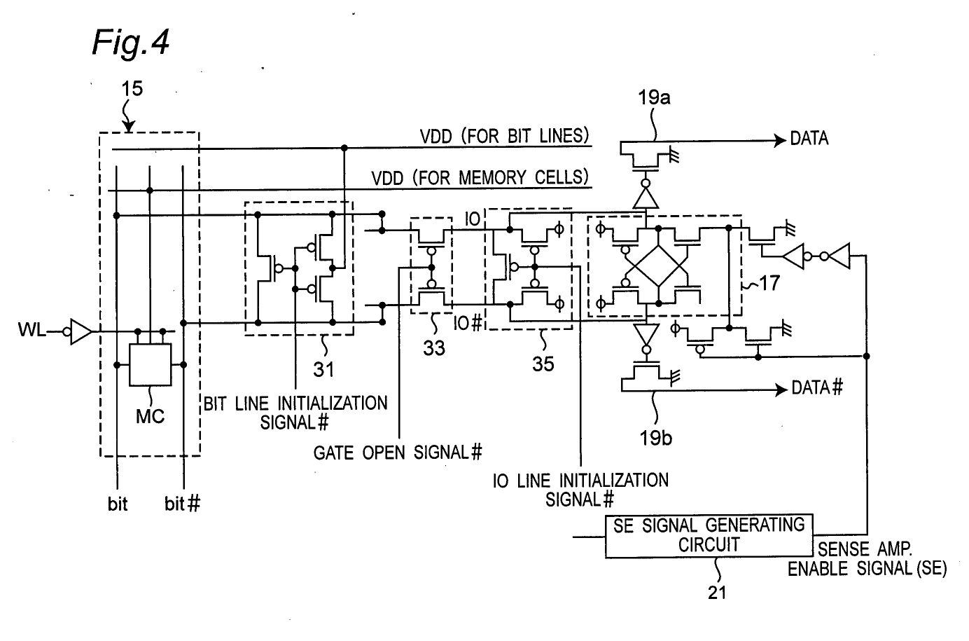

FIG. 4 is a detailed block diagram of a block 10 in FIG. 2. The bit line pair “bit” and “bit#” connected to the memory cell MC in the memory cell array 15 is connected to a bit line initialization circuit 31 and a transfer gate 33.

The bit line pair “bit” and “bit #” is connected to an IO line pair IO and IO# through the transfer gate 33. The IO line pair IO and IO# is connected to a read data bus 19a and 19b through the sense amplifier 17.

The bit line initialization circuit 31 initializes the bit line pair “bit” and “bit#” in advance of the data read operation (to set voltages of bit lines at a power supply voltage (VDD), for example, 1.8 V). The bit-line initialization circuit 31 is activated by a bit-line initialization signal#.

The transfer gate 33 controls transfer of the voltage of the bit line pair to the IO line pair IO and IO#. The transfer gate 33 is controlled by a gate open signal#.

An IO line initialization circuit 35 initializes the IO line pair IO and IO#, and is activated by an IO line initialization signal#. It should be noted that the IO-line initialization signal# rises up when the word line is selected and a fall timing is decided by performing an OR operation of the external clock signal and the sense amplifier enable signal.

The sense amplifier 17 amplifies the minute voltage of the bit line pair that corresponds to data held in the memory cell and is transferred through the IO line pair IO and IO#. As described above, the sense amplifier 17 is activated by the sense amplifier enable signal (SE signal). The amplified voltage in the sense amplifier 17 is transferred to the read-data bus 19a and 19b, and read out as the data value.

The operation of the semiconductor memory constructed as above will be described in detail below.

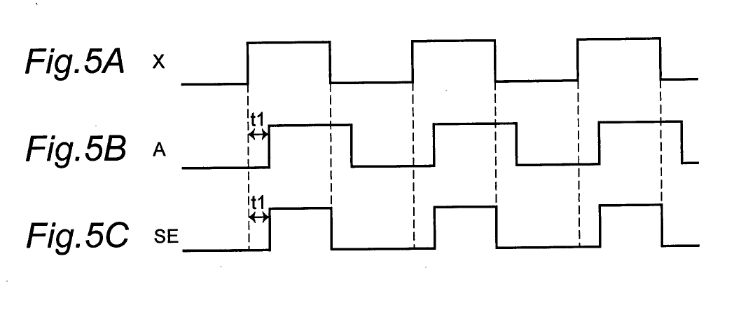

With reference to FIGS. 5A to 5C, the operation of the SE signal generating circuit 21 shown in FIG. 1 will first be described. FIG. 5A shows a waveform of an internal clock signal X which enters into the SE signal generating circuit 21. FIG. 5B shows a waveform of an output signal of the delay circuit 23, that is, a signal A obtained by delaying the internal clock signal X by a predetermined time t1. FIG. 5C shows a waveform of an output signal SE from the SE signal generating circuit 21. As shown in these figures, the SE signal generating circuit 21 generates the signal SE based on the internal clock signal X and the signal A obtained by delaying the internal clock signal X, so that the signal SE has a rising timing delayed by the time t1 with respect to that of the internal clock signal X and the same falling timing as that of the internal clock signal X. When a cycle of the internal clock signal is T, a delay of the internal clock signal X by a time (T-t1) can provide a signal having a falling timing advanced by the time t1 with respect to that of the internal clock signal X with the same rising timing as that of the internal clock signal X. Alternatively, in generating the signal SE, when the rising timing of the internal clock signal is delayed by a predetermined time t1, the falling timing of the internal clock signal may be delayed by a time shorter than the predetermined time t1. Preferably, the predetermined time t1 is set in the range from 0.2 to 0.3 nanoseconds to assure a sufficient time margin (about one nanosecond) between the selection of the word line and the initiation of the activation of the sense amplifier 17.

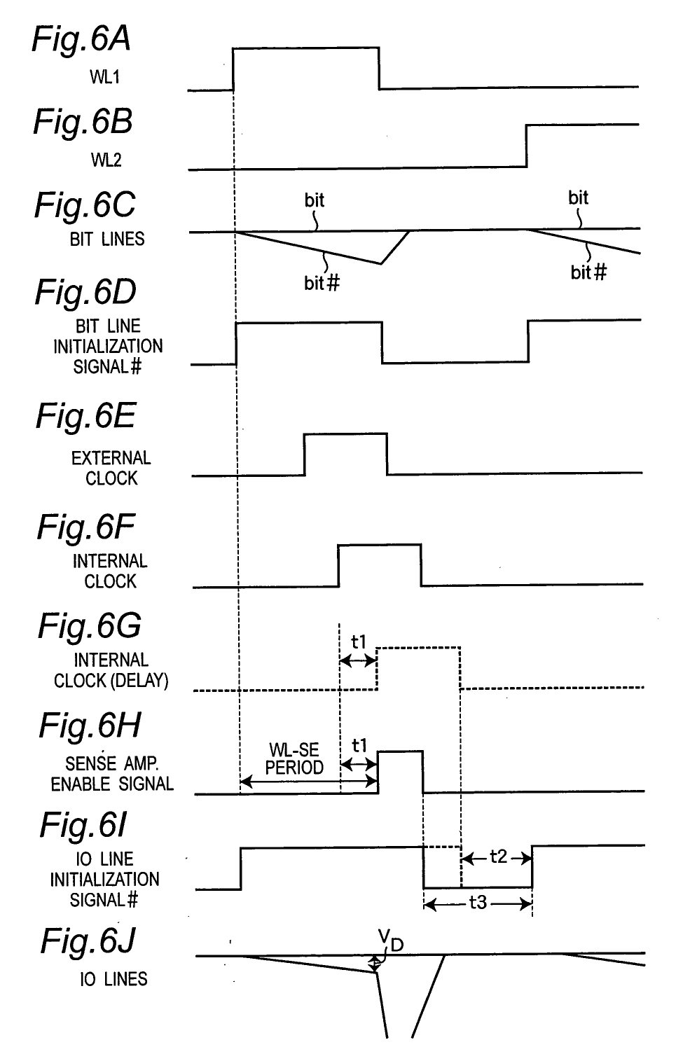

The data read operation of the semiconductor memory will be secondly described with reference to FIGS. 6A to 6J. As shown FIG. 6A, when the word line WL1 is selected (brought into the “High” state), the bit-line initialization signal# produced from the external clock signal is brought into the “High” state. Thus, the initialization state of the corresponding bit line pair is released, and then a voltage equivalent to data held in the corresponding memory cell will appear on the bit line pair. In FIGS. 6A to 6J, it is assumed that the data held in the memory cell which is connected to the word line to be subjected to the data read operation is in the “High” state. In this case, the bit line “bit#” is gradually brought into the “Low” state.

During the data read operation, the transfer gate 33 connecting the bit lines and the IO lines is opened, and thereby the voltage of (or potential difference between) the bit lines is transferred directly to IO lines.

The IO-line initialization signal# rises in conjunction with the selection of the word line WL1 to release the initialization state of the IO line pair. This allows the voltage on the bit line pair to be transferred to the IO line pair. Since an amplitude of the voltage on the bit line pair is small or in an undetectable level, the voltage should be amplified by the sense amplifier 17. For this purpose, the sense amplifier 17 is activated by the sense amplifier enable signal SE. The voltage of the bit line pair is amplified up to a detectable level or a CMOS level (e.g. 1.8 V), and the data is transferred to the read data bus 19a and 19b.

The falling timing of the IO line initialization signal# is given by performing an OR operation of the external clock signal and the sense amplifier enable signal as described above. Thus, when both the external clock signal (see FIG. 6E) and the sense amplifier enable signal (see FIG. 6H) are in the “Low” state (see FIG. 6I), the IO line initialization signal# is brought into the “Low” state to initialize the IO line pair.

As for the timing of initiating the activation of the sense amplifier 17, it is desirable to activate the sense amplifier 17 after a sufficient voltage has appeared on the IO lines. More specifically, it is desirable to activate the sense amplifier 17 at a time when the voltage V_{D} on the IO lines gradually increasing as a time elapsing reaches a value greater than the minimum voltage which is detectable by the sense amplifier 17. It should be noted that the sense amplifier 17 may be activated when the voltage difference between bit lines “bit” and “bit#” is sufficiently increased, because the bit line pair and the IO line pair have approximately the same operational characteristic. Specifically, it is preferable to activate the sense amplifier 17 when the voltage V_{D} or the voltage difference between bit lines “bit” and “bit#” is increased to 30 mV or more, further preferably 50 mV or more.

In case of using the internal clock signal appearing firstly after the selection of the word line WL1, as shown in FIG. 6F, as the SE signal for activating the sense amplifier 17, it is hardly to assure a sufficient time margin (WL-SE period) required for increasing the voltage of the IO line pair up to a sufficient value. A preferred value of the WL-SE period is about one nanosecond or more.

In such a situation, there is a way to obtain a signal as shown in FIG. 6G by delaying the internal clock signal of FIG. 6F by a predetermined time t1 (e.g. 0.2 to 0.3 nanoseconds) and use the obtained signal as the SE signal. However, by that way, the falling timing of the delayed internal clock signal is also delayed, and thus the falling timing of the IO line initialization signal# is undesirably delayed as shown by the dotted line in FIG. 6I to provide a reduced initialization as a period t2.

On the contrary, according to the present invention, the SE signal generating circuit 21 as shown in FIG. 1 generates the SE signal from the internal clock, and therefore can produce the SE signal with a delayed rising timing and the same falling timing as that of the internal clock signal. Thus, the falling timing of the IO line initialization signal# is never delayed, as shown by the solid line in FIG. 6I. This makes it possible to assure an sufficient initialization period t3 while ensuring an sufficient WL-SE period as shown in FIG. 6H.

Consequently, the SE signal generating circuit according to the present embodiment can generate an enable signal of the sense amplifier with a simplified structure while assuring a sufficient initialization period even though using a high speed clock signal. In addition, using such an SE signal generating circuit, a semiconductor memory device (e.g. synchronous SRAM) capable of a high speed processing using a high-speed clock signal can be achieved.

### Second Embodiment

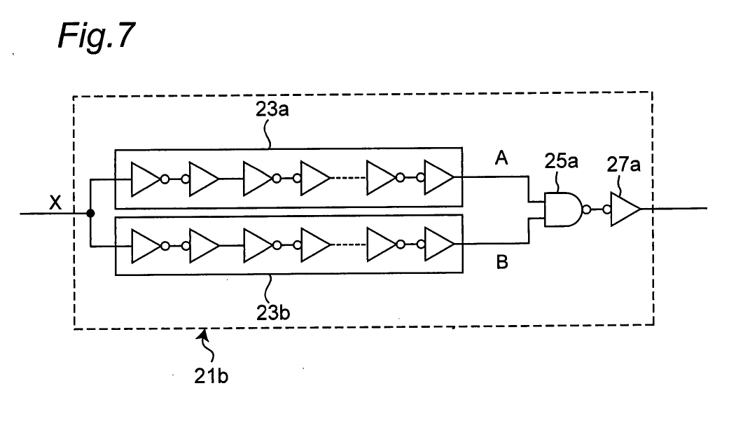

FIG. 7 shows another configuration of an SE signal generating circuit for generating an enable signal of the sense amplifier. The SE signal generating circuit 21b according to the present embodiment includes a pair of delay circuits 23a and 23b, and a set of a NAND gate 25a and an inverter 27a which perform an AND operation of respective outputs from the delay circuits 23a and 23b.

Each of the delay circuits 23a and 23b includes a plurality of inverters each serving as an delay element. The number of the delay elements to be includes in the delay circuit A is determined based on a delay time. The difference between the respective delay times of the delay circuits 23a and 23b corresponds to the delay time t1 of the delay circuit 23 in the first embodiment.

The SE signal generating circuit 21b according to the second embodiment is intended to assure a sufficient initialization period as with that in the first embodiment, and to facilitate efficient modification process after completion of a design phase. That is, the SE signal generating circuit 21b is provided with the pair of delay circuits each including the delay elements arranged in plural stages. Hence, when the time difference (delay time) between two signals to be entered into the NAND gate 25a is modified due to a design change and so on after completion of the design phase (i.e. after production of mask patters), the delay time can be modified only by making a change to a minimum number of mask patters. More specifically, the delay time can be modified only by changing the stage number of the delay elements, and this can be flexibly changed only by making a change in mask patterns relating to aluminum wiring connecting between the respective delay elements. Thus, the timing of the SE signal can be modified with highly enhanced flexibility.

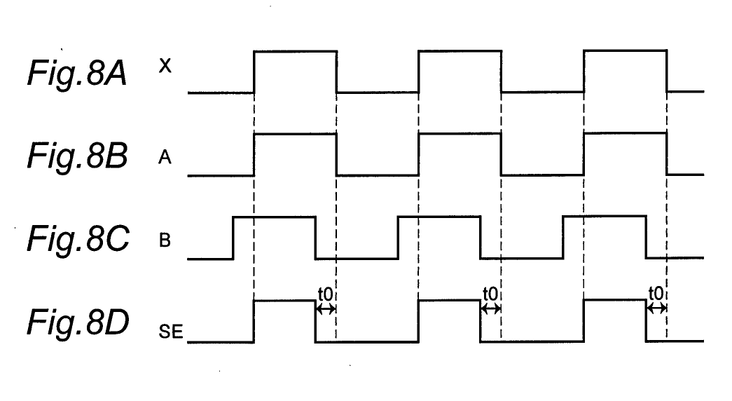

FIGS. 8A to 8D show waveforms of signals at respective sections of the SE signal generating circuit 21b adapted to generate a SE signal having a falling timing advanced by a time t0 with respect to the entered internal clock signal X. The delay circuit 23a outputs a signal A produced by delaying the internal clock signal X by the cycle (T) of the clock signal X, and the delay circuit 23b outputs a signal B advanced by a time t0 (or a signal delayed by (T-t0)) with respect to the signal A.

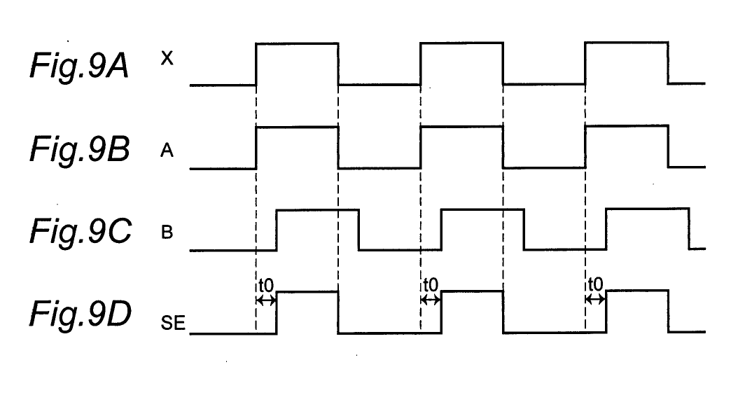

FIGS. 9A to 9D show waveforms signals at respective sections of the SE signal generating circuit 21b adapted to generate a SE signal having a rising timing delayed by a time t0 with respect to the entered internal clock signal X. The delay circuit 23a outputs a signal A produced by delaying the internal clock signal X by its cycle time (T), and the delay circuit 23b outputs a signal B delayed by the time t0 with respect to the signal A.

Thus, the stage number of the delay elements in each of the delay circuits 23a and 23b may be adjusted to obtain the signals A and B as shown in FIGS. 8B and 8C when it is desired to generate the signal SE having the falling timing advanced by the time t0 with respect to the entered internal clock signal X, or adjusted to obtain the signals A and B as shown in FIGS. 9B and 9C when it is desired to generate the signal SE having the rising timing delayed by the time t0 with respect to the entered internal clock signal X.

Thus, according to the SE signal generating circuit of this embodiment, in the modification process after completion of a design phase (after production of mask patterns), it is possible to adjust a relative delay amount between signals to be entered into the NAND circuit 25a by appropriately reducing the stage number of the delay elements included in the two delay circuits. Such an adjustment can be conducted only by changing the mask patterns relating to conductors between the respective delay elements. This makes it possible to facilitate efficient modification process after completion of a design phase (after the production of the mask patterns).

While the present invention has been described by reference to the specific embodiments, various modifications and alterations will become apparent to those skilled in the art. Therefore, it is not intended that the present invention be limited to the illustrative embodiments herein, but only by the appended claims and their equivalents.

What is claimed is:

1. A semiconductor memory device operating in synchronization with an external clock signal, comprising:
memory cells arrayed in two dimension;
word lines and bit lines connected to the memory cells;
IO lines connected to the bit lines; and
a sense amplifier connected to the IO lines and activated by a sense amplifier enable signal,
wherein after the word line is selected, an internal clock signal is generated by delaying the rising and falling edges of the external clock signal input to the memory device, and
wherein a timing at which the internal clock signal changes from a first state to a second state is delayed by a predetermined time to make the sense amplifier enable signal active, and a timing at which the internal clock signal changes from the second state to the first state is delayed by a shorter period than the predetermined time to make the sense amplifier enable signal inactive.

2. The semiconductor memory device according to claim 1, wherein potential of the IO lines are initialized before the word line is selected, the initialization of the IO lines are terminated according to the selection of the word line, and the IO lines are initialized again according to the change of the external clock signal from the second state to the first state and the inactivation of the sense amplifier enable signal.

3. A semiconductor memory device operating in synchronization with an external clock signal, comprising:
memory cells arrayed in two dimension;
word lines and bit lines connected to memory cells;
IO lines connected to bit lines;
a sense amplifier connected to the IO lines and activated by a sense amplifier enable signal;
a first delay circuit operable to delay an internal clock signal by a first predetermined time, the internal clock signal being generated by delaying the rising and falling edges of the external clock signal input to the memory device after the word line is selected;
a second delay circuit operable to delay the internal clock signal by a second predetermined time; and
an AND circuit operable to logically multiply an output signal from the first delay circuit and an output signal from the second delay circuit to generate the sense amplifier enable signal.

4. The semiconductor memory device according to claim 3, wherein the first or second delay circuit comprises a delay stages including multiple stages of delay elements and the number of delay stages can be modified by changing the wiring pattern of the delay stages.
